(19) United States
(12) Patent Application Publication
(10) Pub. No.: US 2017/0162430 A1
(43) Pub. Date: Jun. 8, 2017

(54) METHODS FOR PRODUCING INTEGRATED CIRCUITS WITH AIR GAPS AND INTEGRATED CIRCUITS PRODUCED FROM SUCH METHODS

(71) Applicant: GLOBALFOUNDRIES, Inc., Grand Cayman (KY)

(72) Inventors: Xintuo Dai, Malta, NY (US); Huang Liu, Malta, NY (US); Chang Ho Maeng, Malta, NY (US)

(21) Appl. No.: 14/958,224

(22) Filed: Dec. 3, 2015

(51) Int. Cl. H01L 21/764; H01L 23/31; H01L 23/528; H01L 21/768; H01L 23/535

(52) U.S. Cl. CPC H01L 21/764; H01L 21/76802; H01L 21/76877; H01L 21/76829; H01L 23/535; H01L 23/528; H01L 23/3107

(57) ABSTRACT

Methods for producing integrated circuits and integrated circuits produced by such methods are provided. In an exemplary embodiment, a method for producing an integrated circuit includes forming a base dielectric layer overlying a substrate. A sacrificial layer is formed overlying the base dielectric layer, and adjacent conductive components are formed in the sacrificial layer where the adjacent conductive components are physically separated by material of the sacrificial layer. The sacrificial layer is removed such that an air gap is defined between the adjacent conductive components, where the air gap overlies the base dielectric layer. A cap dielectric layer is formed overlying the base dielectric layer and the air gap to enclose the air gap within the integrated circuit.

### TECHNICAL FIELD

The technical field generally relates to methods for producing integrated circuits with air gaps and integrated circuits produced from such methods, and more particularly relates to methods for producing integrated circuits with air gaps positioned between adjacent conductive components and integrated circuits produced from such methods.

### BACKGROUND

The semiconductor industry is continuously moving toward the fabrication of smaller and more complex microelectronic components with higher performance. The production of smaller integrated circuits requires the development of smaller electronic components, and closer spacing of those electronic components within the integrated circuits. Electromagnetic interference can degrade the performance of electronic components that are spaced too close together within the integrated circuits, but electronic components that are positioned close together can be separated by an insulating material with a low dielectric constant to minimize disruptive interference.

Many materials have low dielectric constants, but a vacuum has the lowest dielectric constant. Gases, such as air, have very low dielectric constants and the dielectric constant of air is nearly the same as that of a vacuum. For example, vacuum has a dielectric constant of 1, and air at about 1 atmosphere has a dielectric constant of less than about 1.01. However, air or other gases provide essentially no structural support, and this limits the use of air or other gases as dielectric materials in integrated circuits. Processes for producing air gaps are frequently modified because the air gap can be filled if it is breached during production. The limited space for air gaps makes protective barriers or other protective steps difficult to implement, and sequential production techniques for different structures often increases the cost over simultaneous production techniques. Multiple etching steps are often used to form air gaps, so some components are increased in size to withstand the multiple etchings. However, the larger size of the components adjacent to the air gaps limits the ability to produce smaller integrated circuits. The destructive etch effects can also decrease reliability of the integrated circuit.

Accordingly, it is desirable to provide integrated circuits with air gaps and methods of producing integrated circuits that enable simultaneous production of different components. In addition, it is desirable to provide methods of producing integrated circuits with air gaps while minimizing process steps. Furthermore, other desirable features and characteristics of the present embodiment will become apparent from the subsequent detailed description and the appended claims, taken in conjunction with the accompanying drawings and this background of the invention.

### BRIEF SUMMARY

Methods for producing integrated circuits and integrated circuits produced by such methods are provided. In an exemplary embodiment, a method for producing an integrated circuit includes forming a base dielectric layer overlying a substrate. A sacrificial layer is formed overlying the base dielectric layer, and adjacent conductive components are formed in the sacrificial layer where the adjacent conductive components are physically separated by material of the sacrificial layer. The sacrificial layer is removed such that an air gap is defined between the adjacent conductive components, where the air gap overlies the base dielectric layer. A cap dielectric layer is formed overlying the base dielectric layer and the air gap to enclose the air gap within the integrated circuit.

A method for producing an integrated circuit is provided in another embodiment. A base dielectric layer is formed overlying a substrate, and a sacrificial layer is formed overlying the base dielectric layer. A hard mask is formed overlying the sacrificial layer, where the hard mask includes a first hard mask layer, a second hard mask layer overlying the first hard mask layer, and a third hard mask layer overlying a second hard mask layer. A third pattern is formed in the third hard mask layer by removing selected portions of the third hard mask layer, and a second pattern is formed in the second hard mask layer by removing selected portions of the second hard mask layer. A via is formed by removing the sacrificial layer and the base dielectric layer underlying the second pattern and removing the sacrificial layer underlying the third patter. A conductive component is formed in the via.

An integrated circuit is provided in yet another embodiment. The integrated circuit includes a base dielectric layer overlying a substrate. Adjacent conductive components are disposed within the base dielectric layer. An air gap is defined between the adjacent conductive components, and the air gap is defined over the base dielectric layer. A seal layer overlies the adjacent conductive components and the base dielectric layer, and a cap dielectric layer overlies the air gap and underlies the seal layer.

### BRIEF DESCRIPTION OF THE DRAWINGS

The present embodiments will hereinafter be described in conjunction with the following drawing figures, wherein like numerals denote like elements, and wherein:

FIGS. 1-3, 5, 6, and 8-15 illustrate, in cross sectional views, a portion of an integrated circuit and methods for its fabrication in accordance with exemplary embodiments; and

FIGS. 4 and 7 illustrate the integrated circuit and methods for its fabrication in sectional perspective views.

### DETAILED DESCRIPTION

The following detailed description is merely exemplary in nature and is not intended to limit the various embodiments or the application and uses thereof. Furthermore, there is no intention to be bound by any theory presented in the preceding background or the following detailed description. Embodiments of the present disclosure are generally directed to integrated circuits and methods for fabricating the same. The various tasks and process steps described herein may be incorporated into a more comprehensive procedure or process having additional steps or functionality not described in detail herein. In particular, various steps in the manufacture of integrated circuits are well-known and so, in the interest of brevity, many conventional steps will only be mentioned briefly herein or will be omitted entirely without providing the well-known process details.

An integrated circuit includes air gaps between adjacent conductive elements, such as between contacts and/or interconnects. The various conductive elements are formed using a sacrificial layer and a hard mask with a plurality of separate layers, so different conductive elements can be simultaneously formed. A cap dielectric layer is formed overlying the conductive elements, where the cap dielectric layer “bridges” a gap between adjacent conductive elements to seal or enclose the air gap within the integrated circuit.

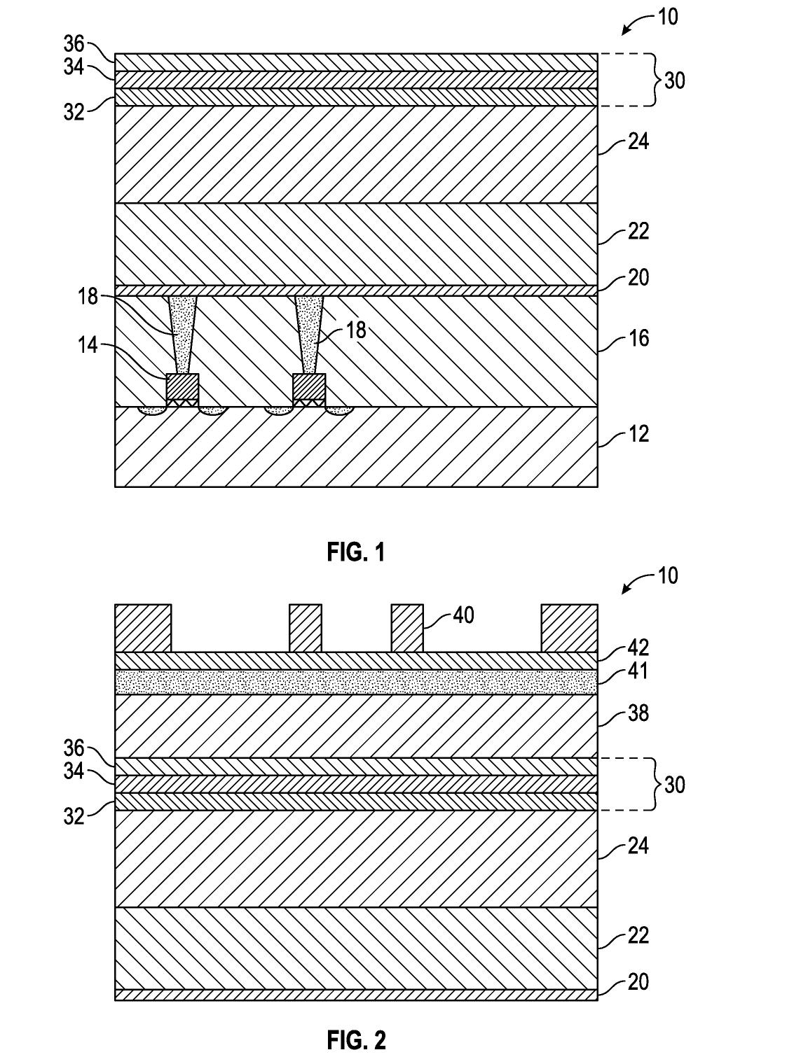

Referring to FIG. 1, an integrated circuit 10 includes a substrate 12 and an electronic component 14. As used herein, the term “substrate” will be used to encompass semiconductor materials conventionally used in the semiconductor industry from which to make electrical devices. Semiconductor materials include monocrystalline silicon materials, such as the relatively pure or lightly impurity-doped monocrystalline silicon materials typically used in the semiconductor industry, as well as polycrystalline silicon materials, and silicon admixed with other elements such as germanium, carbon, and the like. Semiconductor material also includes other materials such as relatively pure and impurity-doped germanium, gallium arsenide, zinc oxide, glass, and the like. In an exemplary embodiment, the semiconductor material is a monocrystalline silicon substrate. The silicon substrate may be a bulk silicon wafer or may be a thin layer of silicon on an insulating layer (commonly known as silicon-on-insulator or SOI) that, in turn, is supported by a carrier wafer.

Suitable electronic components 14 may be a wide variety of components, such as transistors (e.g., metal oxide semiconductor field effect transistors (MOSFET), complementary metal oxide semiconductor (CMOS) transistors, bipolar junction transistors (BJT), high voltage transistors, high frequency transistors, p-channel and/or n-channel field effect transistors (PFETs/NFETs), etc.); resistors; diodes; capacitors; inductors; fuses; or other suitable elements. An interlayer dielectric 16 may overlie the substrate 12, and a component contact 18 may pass through the interlayer dielectric 16 and be in electrical communication with the electronic component 14. As used herein, the term “overlying” means “over” such that an intervening layer may lie between the interlayer dielectric 16 and the substrate 12, and “on” such that the interlayer dielectric 16 physically contacts the substrate 12. There may be more than one layer of interlayer dielectric, so electrical connections between the electronic component 14 and the component contact 18 may be routed through other electrically conductive components, such as other contacts and/or interconnects.

In an exemplary embodiment, a base etch stop 20 is formed overlying the interlayer dielectric 16 and the component contacts 18. The base etch stop 20 may include aluminum nitride, which may be formed by pulsed DC reactive magnetron sputtering, but other materials or other methods of formation may be used in alternate embodiments. For example, silicon carbon nitride may be used in some embodiments. A base dielectric layer 22 is formed overlying the base etch stop 20. In an exemplary embodiment, the base dielectric layer 22 is a low K dielectric material, where a “low K dielectric material” means a material with a dielectric constant less than about 3.9, which is about the dielectric constant of silicon dioxide. Silicon dioxide has been used as an insulating material in many integrated circuits, and silicon dioxide or other materials may be used for the base dielectric layer 22 in some embodiments. Silicon dioxide can be produced several ways, such as by chemical vapor deposition using silane (SiH₄) or tetraethylorthosilicate (TEOS) and O₂, and different forms or densities of silicon dioxide may have different dielectric constants. One technique used to lower the dielectric constant of silicon dioxide is to dope it with organic groups to produce organosilicate glass (OSG) with dielectric constants that can range from about 2.7 to about 3.5. OSG may be deposited as a film with a density of about 1.5 grams per cubic centimeter (g/cm³). Porosity has been added to OSG to produce porous OSG insulating materials with a dielectric constant below about 2.7, where the void space in the pores has a dielectric constant of about 1.0. Porous OSG can be created by adding pore-forming compounds (called “porogens”) to silicon-containing precursors during the deposition process, and then removing the porogen after the insulating layer is deposited. The porogen may be an organic compound that can be vaporized or otherwise removed from the insulating layer. Examples of silicon-containing precursors include, but are not limited to, tetramethylcyclotetrasiloxane (TMCTS), diethoxymethylsilane (DEMS), dimethyldimethoxysilane (DMDMOS), trimethylsilane (3MS), TEOS, triethoxysilane, di-tert-butoxysilane, and di-tert-butoxydiacetoxysilane.

In an exemplary embodiment, a sacrificial layer 24 is formed overlying the base dielectric layer 22. The sacrificial layer 24 may include amorphous carbon, which can be deposited by spinning a fullerene compound or other compounds with aryl groups having hydroxyl and/or carboxylic functional groups combined with a crosslinking material on to the base dielectric layer 22. The amorphous carbon material is then formed by curing, such as by heating to a temperature of about 400 degrees centigrade (° C.) for about 5 minutes. Organic polymers or other materials may be used for the sacrificial layer 24 in alternate embodiments. In some embodiments, the integrated circuit 10 is maintained at or below a threshold temperature that may damage the sacrificial layer 24 while the sacrificial layer 24 is in place. For example, some amorphous carbon materials that may be included in the sacrificial layer 24 will decompose when heated above a threshold temperature, such as above about 400° C. Therefore, fabrication temperatures are maintained at or below about 400° C. while the sacrificial layer 24 is in place.

A hard mask 30 is then formed overlying the sacrificial layer 24. In some embodiments and as shown in FIG. 1, the hard mask 30 includes a first hard mask layer 32, a second hard mask layer 34 overlying the first hard mask layer 32, and a third hard mask layer 36 overlying the second hard mask layer 34. The first, second, and third hard mask layers 32, 34, 36 may be formed from different materials so each layer can be selectively removed. In an exemplary embodiment, the first hard mask layer 32 includes silicon nitride, the second hard mask layer 34 includes silicon dioxide, and the third hard mask layer 36 includes titanium nitride, but other materials may be used in alternate embodiments. Silicon nitride can be formed by reacting ammonia with dichlorosilane in a low pressure chemical vapor deposition furnace, silicon dioxide can be formed by chemical vapor deposition using silane and oxygen, and titanium nitride can be formed by chemical vapor deposition with tetramethylamidotitanium and nitrogen trifluoride, but other methods of forming the different layers of the hard mask 30 may be used in alternate embodiments.

Referring to an exemplary embodiment in FIG. 2, an optional third planarization layer 38 is formed overlying the hard mask 30, and a third photoresist layer 40 is formed overlying the third planarization layer 38. An optional third mask layer 41 and a third antireflective layer 42 are formed between the third photoresist layer and the third planarization layer 38. The third planarization layer 38, third photoresist layer 40, third mask layer 41, and third antireflective layer 42 are referred to with the word “third” because they are used in the patterning of the third hard mask layer 36, as described below. The third planarization layer 38 is carbon based in an exemplary embodiment, and may include an organic polymer that is spun in a liquid form onto the hard mask 30 and then cured with a baking process at a temperature of from about 200° C. to about 400° C. In an exemplary embodiment, the third mask layer 41 is silicon oxynitride, which may be formed by plasma enhanced chemical vapor deposition using nitrous oxide and silane. Many different materials may be used for the third antireflective layer 42, including inorganic and organic compounds, such as titanium nitride or organosiloxanes. Titanium nitride may be deposited by chemical vapor deposition using tetramethylamidotitanium and nitrogen trifluoride, and organosiloxanes may be deposited by spin coating. Anti-reflective coatings may improve the accuracy and critical dimensions during photoresist patterning. The third photoresist layer 40 (and other photoresist layers described below) is deposited by spin coating, and patterned by exposure to light or other electromagnetic radiation through a mask with transparent sections and opaque sections. The light causes a chemical change in the photoresist such that either the exposed portion or the non-exposed portion can be selectively removed. The desired locations are removed with an organic solvent, and the third photoresist layer 40 remains overlying the other areas of the hard mask 30.

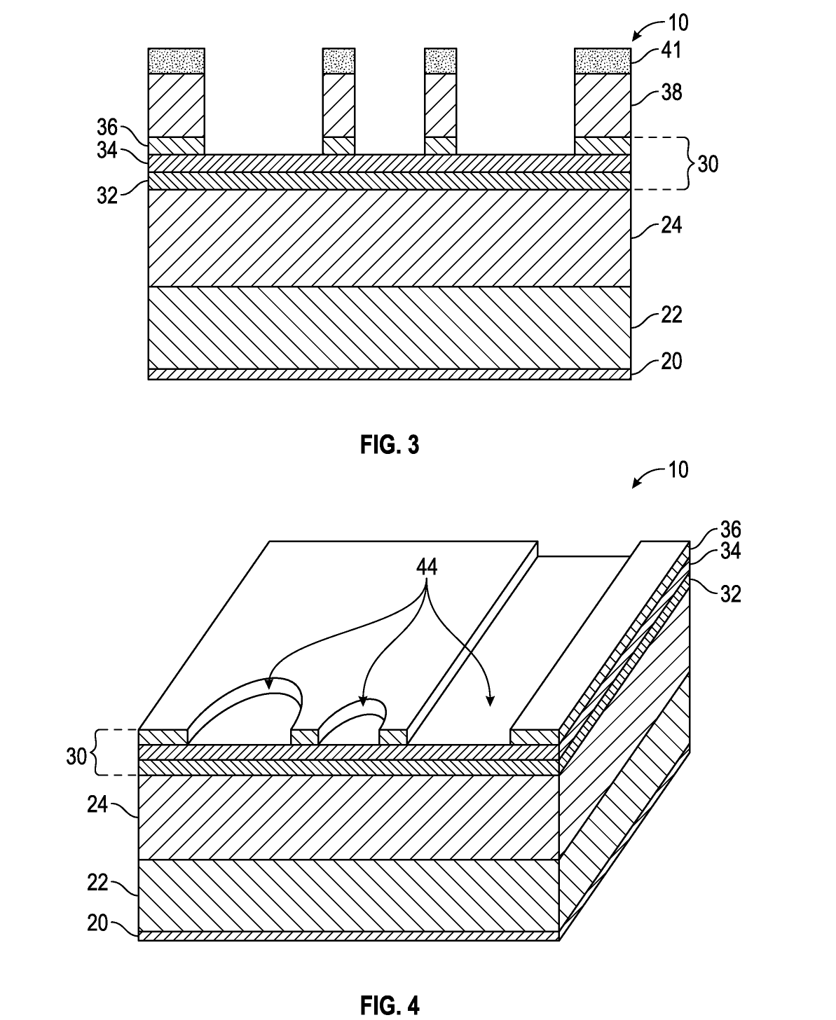

The third hard mask layer 36 is removed at selected locations that are defined by the patterning of the third photoresist layer 40, as illustrated in FIG. 3 with continuing reference to FIG. 2. In an exemplary embodiment, the third mask layer 41, the third antireflective layer 42, and the third planarization layer 38 are removed in the area defined by the patterning of the third photoresist layer 40. The third antireflective layer 42 may include an organic material that can be removed with a reactive ion etch using nitrogen and oxygen, the third planarization layer 38 may be removed with a reactive ion etch using carbon tetrafluoride, and the third mask layer 41 may be removed with a reactive ion etch using trifluoromethane, but other etchants can be used in alternate embodiments, which may depend on the materials used. Once the photoresist pattern is transferred to the third planarization layer 38, the third photoresist layer 40, the third mask layer 41, and the third antireflective layer 42 may be removed, such as with an oxygen containing plasma for the third photoresist layer 40, and a wet etch with nitric acid and hydrofluoric acid for the third antireflective layer 42, and a reactive ion etch with trifluoromethane for the third mask layer 41, but other etchants or etch methods can be used in alternate embodiments. In an alternate embodiment without the third planarization layer 38, the third hard mask layer 36 may be etched through the patterned third photoresist layer 40 and the third antireflective layer 42. In either case, the third hard mask layer 36 is selectively removed in the area exposed through the third planarization layer 38 or the third photoresist layer 40, where the third planarization layer 38 or the third photoresist layer 40 serves as an etch mask. In an exemplary embodiment where the third hard mask layer 36 includes titanium nitride and the second hard mask layer 34 includes silicon dioxide, the third hard mask layer 36 may be removed using a reactive ion etch with chlorine and argon. After the third hard mask layer 36 is patterned, the third planarization layer 38 may be removed, such as with an inductively coupled plasma using nitrogen and hydrogen or nitrogen and oxygen.

Reference is made to FIG. 4, with continuing reference to FIG. 3. The pattern formed in the third hard mask layer 36 is referred to herein as the “third pattern,” and is referred to with reference number 44. An exemplary embodiment of a portion of the third pattern 44 is illustrated in a sectional perspective view in FIG. 4. As can be seen, a rectangular section of the third hard mask layer 36 has been removed on the right hand side of the figure, a small round section has been removed near the center in the front, where the other half of the small round section is not illustrated, and a larger round section has been removed on the left hand side of the drawing near the front. These different shapes in the third pattern 44 can be used for different components, as described below, and other shapes and/or sizes can be used for other components.

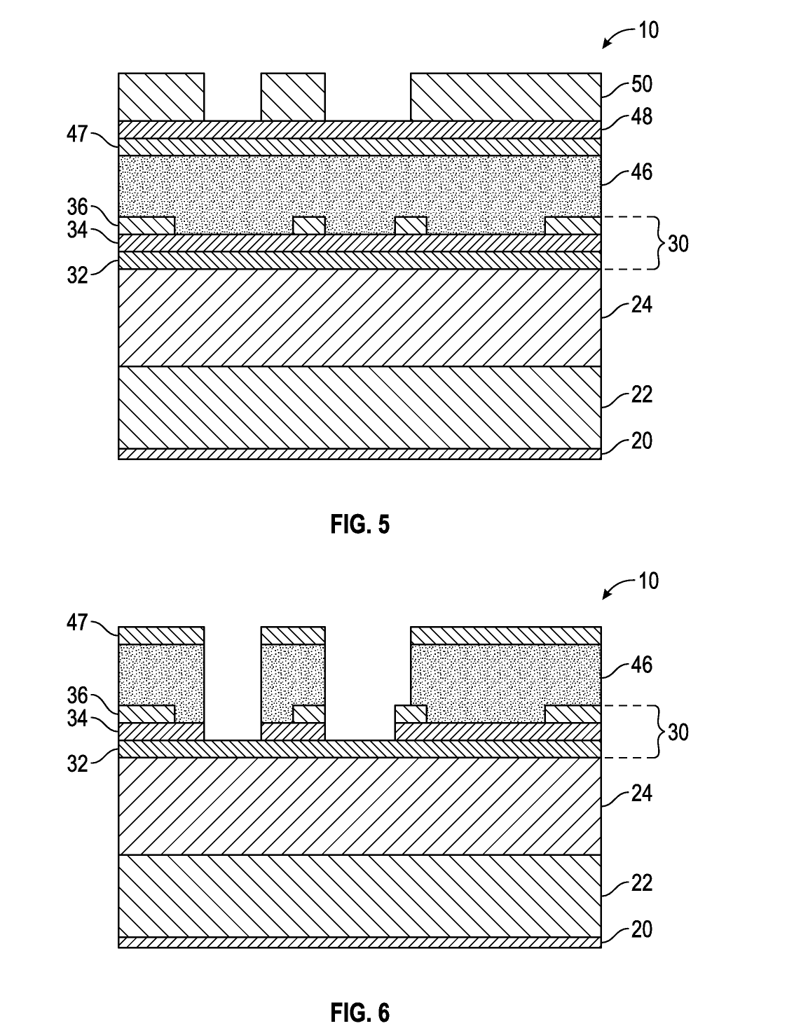

Referring to FIG. 5, an optional second planarization layer 46 is formed overlying the hard mask 30, an optional second mask layer 47 is formed overlying the second planarization layer 46, an optional second antireflective layer 48 is formed overlying the second mask layer 41, and a second photoresist layer 50 is formed overlying the second antireflective layer 48. The second planarization layer 46, the second mask layer 47, the second antireflective layer 48, and the second photoresist layer 50 may be formed and patterned in a similar manner to the third planarization layer 38, the third mask layer 41, the third antireflective layer 42, and the third photoresist layer 40 described above and illustrated in FIG. 2. The second photoresist layer 50 is patterned, and the pattern is transferred to the second hard mask layer 34, as described above and as illustrated in FIG. 6, with continuing reference to FIG. 5. In an exemplary embodiment where the second hard mask layer 34 includes silicon dioxide and the first hard mask layer 32 includes silicon nitride, the second hard mask layer 34 may be removed through the pattern formed in the second planarization layer 46 with a reactive ion etch using carbon tetrafluoride. The first hard mask layer 32 remains in place and protects the sacrificial layer 24, such as from the etch of the second hard mask layer 34 or an ashing process that may be used to remove the second planarization layer 46 after the second hard mask layer 34 has been patterned.

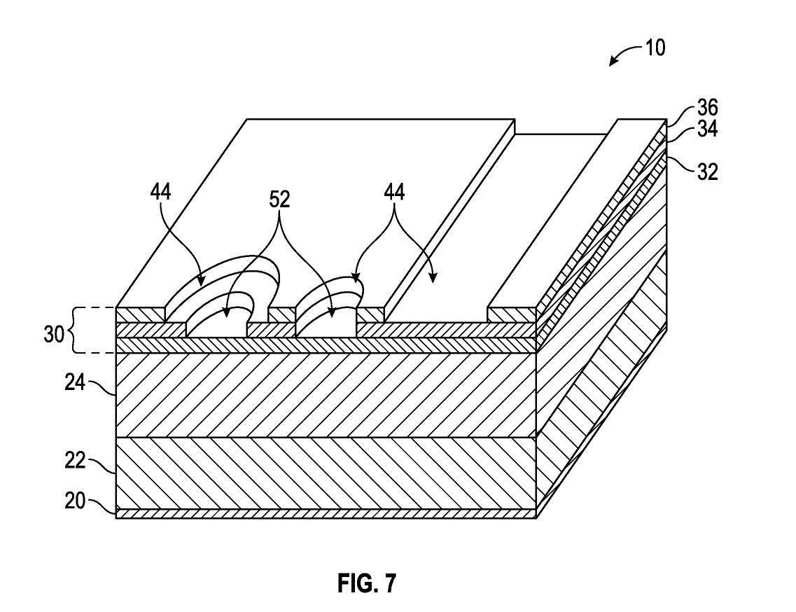

The pattern formed in the second hard mask layer 34 is referred to herein as the “second pattern” and is referred to with reference number 52, as illustrated in an exemplary embodiment in FIG. 7 with continuing reference to FIG. 6 and to FIG. 4. The second pattern 52 is formed within the third pattern 44, because the second hard mask 34 is only removed through gaps in the third hard mask 36 that are part of the third pattern 44. As can be seen, the second pattern 52 may not be within some sections of the third pattern 44, such as in the rectangular portion of the third pattern 44 on the right side of FIGS. 4 and 7. In other locations, the second pattern 52 may match the third pattern 44, such as in the circular location near the center and the front of FIGS. 4 and 7. In yet other locations, the second pattern 52 may be within only a portion of the third pattern 44, such as in the circular location near the left and front of FIGS. 4 and 7, where the second pattern 52 is a smaller circle within the larger circle of the third pattern 44.

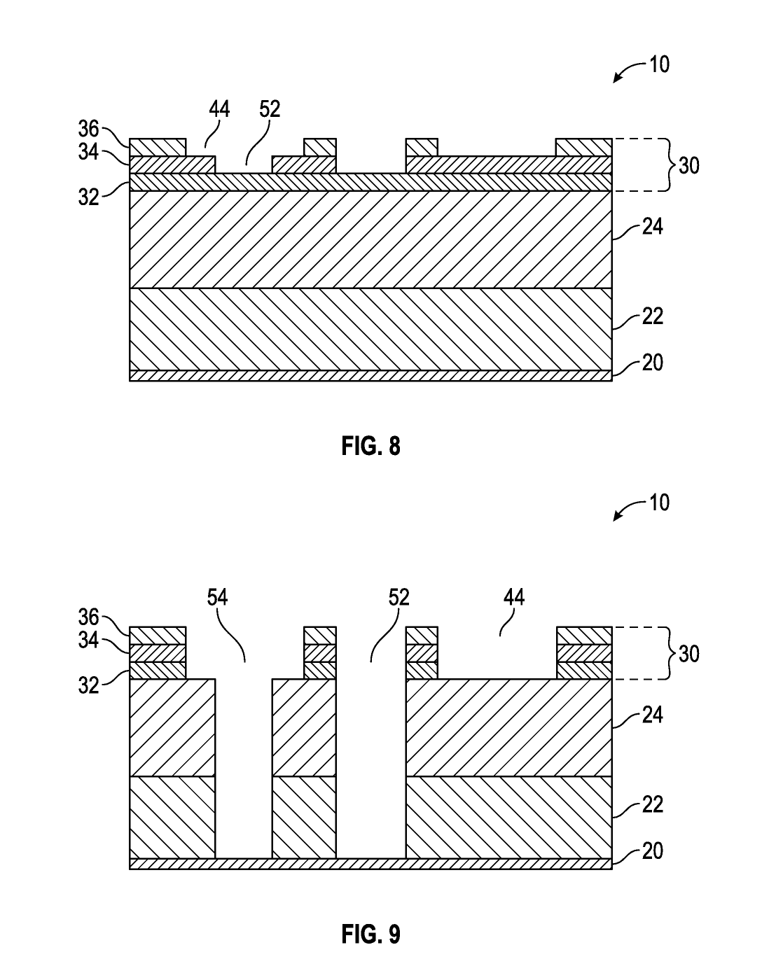

Reference is now made to an exemplary embodiment in FIG. 8, with continuing reference to FIG. 7. The first hard mask layer 32 is removed through the openings of the second hard mask layer 34, so the first hard mask layer 32 is removed in the area directly underlying the second pattern 52. As used herein, the term “directly underlying” means a vertical line passing through the upper area also passes through the lower area, such that the first hard mask layer 32 (the lower area) directly underlying the second pattern (the upper area) are the portions of the first hard mask layer 32 that are removed. It is to be understood that the integrated circuit 10 may be moved such that the relative “up” and “down” positions change, so reference to a “vertical” line means a line that is about perpendicular to the surface of the substrate 12 (illustrated in FIG. 1). The second (and third) hard mask layers 34, 36 may be used as an etch mask for removal of the first hard mask layer 32. In an exemplary embodiment with a silicon nitride first hard mask layer 32, the first hard mask layer 32 is removed with a plasma etch using hydrogen and nitrogen trifluoride, but other etchants could be used in alternate embodiments.

Referring to the embodiment in FIG. 9, with continuing reference to FIG. 7, the sacrificial layer 24 and the base dielectric layer 22 are removed in the area directly underlying the second pattern 52 through the first and second hard mask layers 32, 34 to form a via 54. The via 54 is an opening that is formed through the sacrificial layer 24 and may be formed through the base dielectric layer 22, where the depth of the via 54 may vary for different types of components that will be formed. In an exemplary embodiment where the sacrificial layer 24 includes amorphous carbon and the base dielectric layer 22 includes porous organosilicate glass, the sacrificial layer 24 can be removed with a reactive ion etch using carbonyl sulfide and oxygen, and the base dielectric layer 22 can be subsequently removed with a plasma etch using hexafluorobutadiene, oxygen, and monofluoromethane. Portions of the second hard mask layer 34 and the first hard mask layer 32 that are exposed through the third hard mask layer 36 (i.e. not covered by the third hard mask layer 36) may be removed while removing the base dielectric layer 22. The base etch stop 20 terminates the etch after passing completely through the base dielectric layer 22.

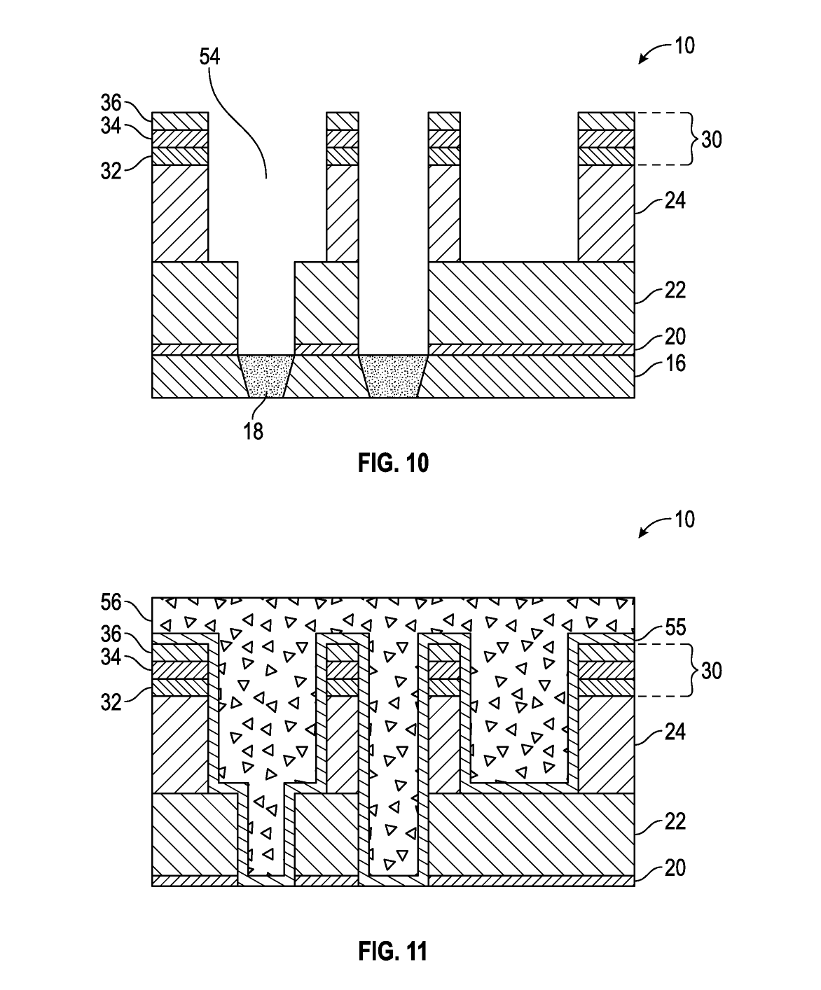

Reference is made to the exemplary embodiment in FIG. 10 with continuing reference to FIG. 7. The second hard mask layer 34 may have been removed from the third pattern 44 with the etch for the base dielectric layer 22 described above. After the second hard mask 34 is removed within the third pattern 44, the sacrificial layer 24 may be removed from the area that directly underlies the third pattern 44. Removal of the sacrificial layer 24 is selective in an exemplary embodiment, where the base dielectric layer 22 is left in place underlying the area where the sacrificial layer 24 was removed. In embodiments where the sacrificial layer 24 includes amorphous carbon and the base dielectric layer 22 includes porous organosilicate glass, the sacrificial layer 24 can be selectively removed with a reactive ion etch using nitrogen and hydrogen, nitrogen and oxygen, or other appropriate materials. The base etch stop 20 may also be removed from the area directly underlying the second pattern 52, as illustrated in FIG. 10 with additional reference to FIG. 9, and the base etch stop 20 may be removed after the sacrificial layer 24 is removed from the area underlying the third pattern 44. In an embodiment where the base etch stop 20 includes aluminum nitride, the base etch stop 20 can be removed with an inductively coupled reactive ion etch using chlorine, boron trichloride, and argon. The component contact 18 (previously illustrated in FIG. 1) is exposed on removal of the base etch stop 20.

The via 54 is filled with an electrically conductive material 56 in an exemplary embodiment illustrated in FIG. 11. As used herein, an “electrically conductive material” is a material with a resistivity of about 1×10⁻⁴ ohm meters or less, and an “electrically insulating material” is a material with a resistivity of about 1×10⁴ ohm meters or more. In one embodiment, a liner layer 55 is conformally formed within the via 54 and overlying exposed areas. The liner layer 55 may include titanium nitride, which can be formed by atomic layer deposition using tetramethylamidotitanium and nitrogen trifluoride. The liner layer 55 may aid or facilitate adhesion of the electrically conductive material 56 to the surfaces within the via 54. In some embodiments, the electrically conductive material 56 includes copper, which may be formed by electroless deposition or by electroplating in a sulfuric acid bath with copper sulfate. A copper seed layer (not illustrated) may be formed before the bulk of the electrically conductive material 56 is formed in place.

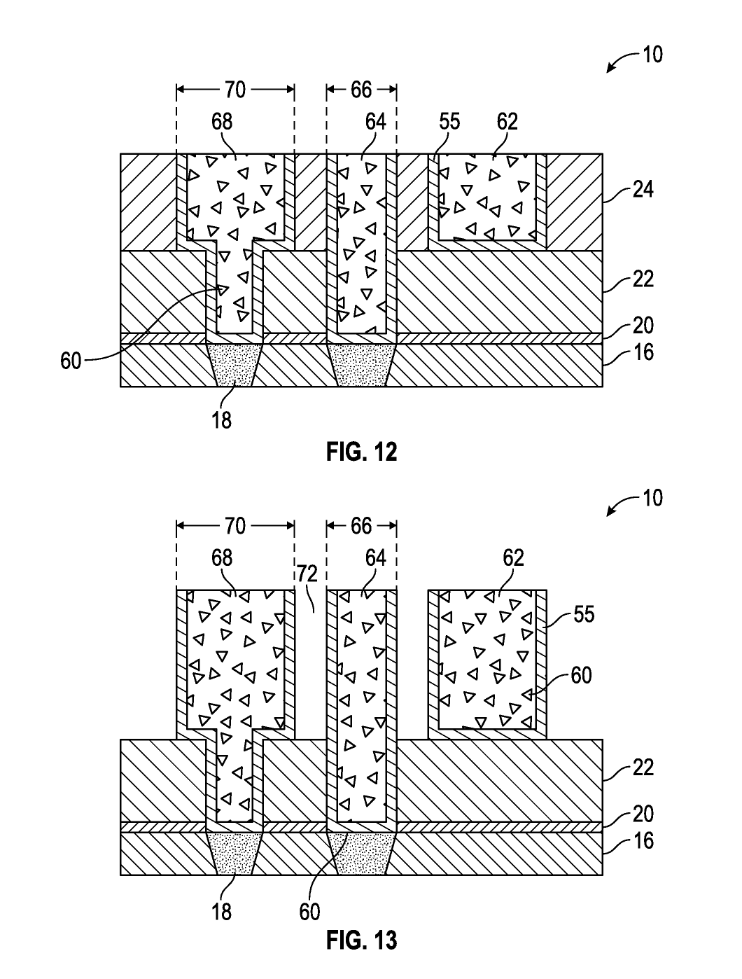

Reference is made to an embodiment illustrated in FIG. 12, with continuing reference to FIG. 11, where FIG. 12 illustrates a portion of the interlayer dielectric previously illustrated in FIG. 1. A plurality of conductive components 60 are formed from the electrically conductive material 56 and the liner layer 55. In an exemplary embodiment, overburden from the electrically conductive material 56 and the liner layer 55 is removed along with any remaining portions of the hard mask 30, such as by chemical mechanical planarization. In some embodiments, the conductive components 60 may include an interconnect 62 and a conductive contact, wherein the conductive contact includes a straight contact 64 and a stepped contact 68. Some of the conductive components 60 are adjacent to each other. The interconnect 62 overlies the base dielectric layer 22 such that the base dielectric layer 22 is between the interconnect 62 and the base etch stop 20 along a vertical line that passes through the interconnect 62, the base etch stop 20, and the base dielectric layer 22. The straight contact 64 is disposed within the sacrificial layer 24 and the base dielectric layer 22, and is electrically connected to a component contact 18 in some embodiments. The straight contact 64 has a straight contact width 66 that is about the same within the sacrificial layer 24 and base dielectric layer 22 and does not have a stepped shape. Reference to the straight contact width 66 staying about the same, as used herein, means the straight contact width 66 changes by about 5 percent or less over a distance of about 1 micron. The stepped contact 68 is also within the sacrificial layer 24 and the base dielectric layer 22, and may also be electrically connected to a component contact 18. The stepped contact 68 has a stepped contact width 70 that is greater within the sacrificial layer 24 than within the base dielectric layer 22, where the stepped contact width 70 changes by about 5 percent or more at the interface between the sacrificial layer 24 and the base dielectric layer 22. The interconnect 62, the straight contact 64, and the stepped contact 68 have different shapes and positions, but are simultaneously formed.

Reference is again made to FIG. 7, with continuing reference to FIGS. 11 and 12. The second pattern 52 is used for the portions of the conductive components 60 that are disposed within the base dielectric layer 22. The third pattern 44 (not including the portion of the third pattern 44 that is within the second pattern 52) is used for the portions of the conductive components 60 that are disposed within the sacrificial layer 24 but that directly overlie the base dielectric layer 22.

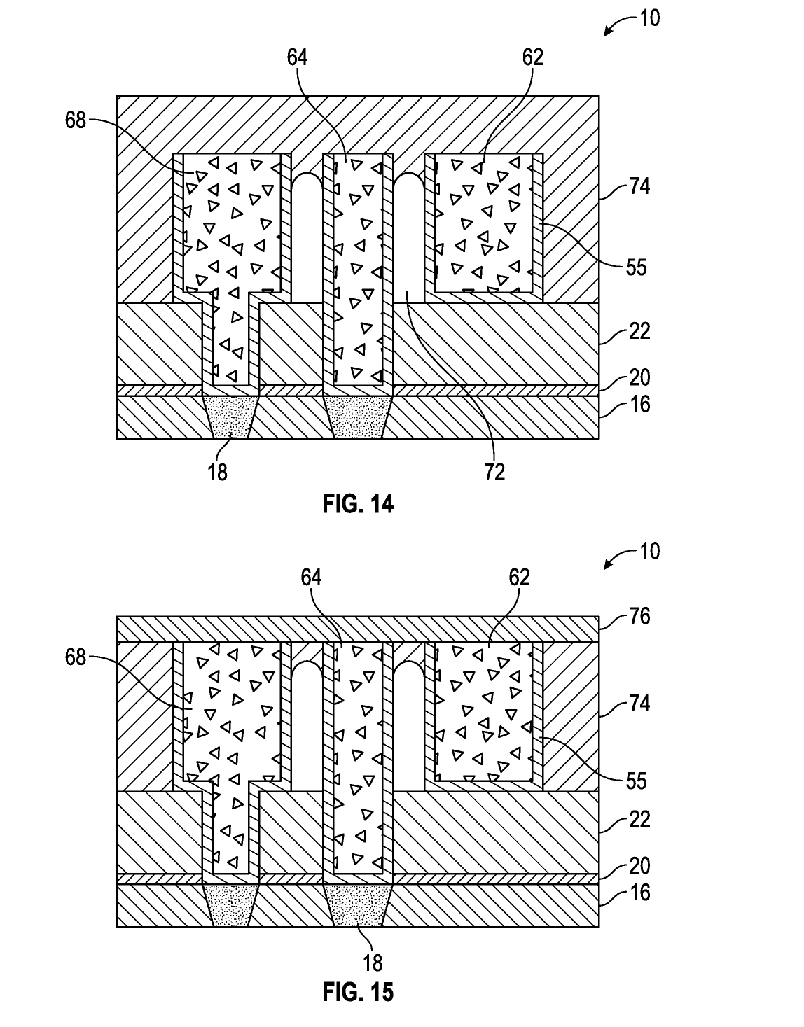

Referring to FIG. 13 with continuing reference to FIG. 12, the sacrificial layer 24 is removed such that an air gap 72 is formed between adjacent conductive components 60. The sacrificial layer 24 may be removed with a reactive ion etch, such as with nitrogen and hydrogen or other etchants, in an exemplary embodiment where the sacrificial layer 24 includes amorphous carbon. In some embodiments, a portion of the base dielectric layer 22 may be removed to recess the base dielectric layer 22 underlying the air gap 72 (not illustrated), such as with an etchant selective to the material of the base dielectric layer 22 over the material of the conductive components 60. In an exemplary embodiment with a base dielectric layer 22 including porous organosilicate glass and conductive components 60 including copper, a timed plasma etch with hexafluorobutadiene, oxygen, and monofluoromethane can be used to recess the base dielectric layer 22 and thereby increase the volume of the air gap 72 between the adjacent conductive components 60. A cap dielectric layer 74 may then be formed overlying the conductive components 60, the base dielectric layer 22, and the air gaps 72 to enclose the air gaps 72 within the integrated circuit 10 between the cap dielectric layer 74 and the base dielectric layer 22, as illustrated in FIG. 14. In an exemplary embodiment, the cap dielectric layer 74 is porous organosilicate glass, as described above for the base dielectric layer 22, but other electrically insulating materials may be used in alternate embodiments. The base and cap dielectric layers 22, 74 may be the same or different materials in various embodiments.

The cap dielectric layer 74 “bridges” the air gap 72 between adjacent conductive components 60, but the cap dielectric layer 74 may fill in the space between some adjacent conductive components 60, so an air gap 72 may not be present between all of the adjacent conductive components 60 in the integrated circuit 10. The cap dielectric layer 74 will bridge the air gap 72 if the distance between adjacent conductive components 60 is less than a critical distance, where the critical distance depends on several factors, such as the viscosity of the cap dielectric layer 74 and the rate at which the cap dielectric layer 74 cures. In an exemplary embodiment, the critical distance between adjacent conductive components 60 for formation of the an air gap 72 is from about 150 to about 5 nanometers, or from about 50 nanometers to about 5 nanometers, or from about 40 nanometers to about 5 nanometers, or from about 32 nanometers to about 5 nanometers in various embodiments. The cap dielectric layer 74 may fill in the space adjacent to the air gap 72, so the critical distance effectively prevents the material of the cap dielectric layer 74 from filling the air gap 72 from the side as well as from the top. A straight line is the shortest distance between the adjacent conductive components 60, and the air gap 72 fills most of the space in a straight line between adjacent conductive components 60 when the distance therebetween is the critical distance or less. This increases the effective dielectric constant between the adjacent conductive components 60. The higher dielectric constant of the cap dielectric layer 74 compared to the air gap 72 is acceptable because electrical interference is reduced by traveling a greater distance around the air gap 72 and through the nearby cap dielectric layer 74.

The cap dielectric layer 74 may physically contact the base dielectric layer 22 in some locations, such as locations where the space between adjacent conductive components or between other structures is large enough for the cap dielectric layer 74 to flow into when in the liquid state. For example, if the space between adjacent conductive components 60 or between other components is about 50 nanometers or more, or about 20 nanometers or more, or about 10 nanometers or more (in various embodiments), the cap dielectric layer 74 may physically contact the base dielectric layer 22 such that no air gap 72 is present in these locations. The cap dielectric layer 74 may extend into the air gap 72 from the top to some extent. The cap dielectric layer 74 may be formed by chemical vapor deposition to form the air gap, as described above, but in alternate embodiments the cap dielectric layer 74 may be formed by a flowable liquid. Adjustments may be made to the viscosity of liquid material used to form the cap dielectric layer 74 to help control the formation of air gaps 72, because more viscous material will bridge over larger distances between adjacent conductive components than less viscous material. The stepped contact width 70 of the upper portion of the stepped contact 68 may be adjusted such that the distance between adjacent conductive components 60 is the critical distance or less. As such, stepped contacts 68 may be incorporated into the integrated circuit 10 to produce air gaps 72 at desired locations by shortening the distance between adjacent conductive components 60 the critical distance or less.

Referring to FIG. 15, the material of the cap dielectric layer 74 overlying the conductive components 60 may be removed, such as by chemical mechanical planarization. The air gaps 72 remain between some adjacent conductive components 60, and a portion of the cap dielectric layer 74 is between the adjacent conductive components 60 and overlying the air gap 72. As such, the air gap 72 is defined by the adjacent conductive components 60 on the side, by the base dielectric layer 22 on the bottom, and by the cap dielectric layer 74 on the top. The cap dielectric layer 74 can be formed in an air atmosphere, so air fills the air gap 72. In alternate embodiments, the cap dielectric layer 74 can be formed in a vacuum, or in a helium, nitrogen, argon, xenon, or other atmosphere, so different gases or a vacuum can be trapped in the air gap 72. The gas in the air gap 72 is a non-polar gas in many embodiments. In some embodiments, a “quenching gas” may be used to reduce the risk of catastrophic electrical discharges, where exemplary quenching gases include, but are not limited to, perfluorocarbons or chlorofluorocarbons. A pressure of about 1 atmosphere in the air gap 72 may reduce stress on the integrated circuit 10, so there is little pressure differential to drive gases to escape or enter the air gap 72 when used at or near atmospheric pressure. However, higher or lower pressures may be used in alternate embodiments. An optional seal layer 76 may be formed overlying the conductive components 60 and the cap dielectric layer 74 in some embodiments, so the cap dielectric layer 74 is between the seal layer 76 and the air gap 72. The seal layer 76 may be formed in a similar manner to the base etch stop 20, as described above, but in alternate embodiments the seal layer 76 may include other materials. In some embodiments, the seal layer 76 is formed of an electrically insulating material. The seal layer 76 may serve in place of a base etch stop layer for a subsequent layer that may be produced in a similar manner to that described above in some embodiments.

While at least one exemplary embodiment has been presented in the foregoing detailed description, it should be appreciated that a vast number of variations exist. It should also be appreciated that the exemplary embodiments are only examples, and are not intended to limit the scope, applicability, or configuration of the application in any way. Rather, the foregoing detailed description will provide those skilled in the art with a convenient road map for implementing one or more embodiments, it being understood that various changes may be made in the function and arrangement of elements described in an exemplary embodiment without departing from the scope, as set forth in the appended claims.

1. A method of producing an integrated circuit comprising:
forming a base dielectric layer overlying a substrate;
forming a sacrificial layer overlying the base dielectric layer;
forming a hard mask overlying the sacrificial layer, wherein the hard mask comprises a first hard mask layer, a second hard mask layer overlying the first hard mask layer, and a third hard mask layer overlying the second hard mask layer;
forming a third pattern in the third hard mask layer by removing selected portions of the third hard mask layer;
forming a second pattern in the second hard mask layer by removing selected portions of the second hard mask layer, wherein the conductive contact directly underlies the second pattern and the interconnect directly underlies the third pattern;
forming a via directly underlying the second pattern, wherein the via extends through the sacrificial layer and the via extends through the base dielectric layer;
removing the sacrificial layer directly underlying the third pattern after forming the via directly underlying the second pattern, wherein removing the sacrificial layer directly underlying the third pattern increases the via such that a width of the via changes at an interface between the sacrificial layer and the base dielectric layer;
forming adjacent conductive components in the sacrificial layer, wherein the adjacent conductive components are physically separated by material of the sacrificial layer;
removing the sacrificial layer such that an air gap is defined between the adjacent conductive components, wherein the air gap overlies the base dielectric layer; and
forming a cap dielectric layer overlying the base dielectric layer and the air gap to enclose the air gap within the integrated circuit.

2. The method of claim 1 wherein forming the adjacent conductive components further comprises:
forming a conductive contact that is within the sacrificial layer and within the base dielectric layer; and
forming an interconnect that overlies the base dielectric layer and is disposed within the sacrificial layer.

3. The method of claim 2 wherein forming the conductive contact comprises forming the conductive contact in electrical connection with a component contact, wherein the component contact underlies the base dielectric layer.

4. The method of claim 1 further comprising:
forming a stepped contact within the via, wherein a stepped contact width changes at the interface between the sacrificial layer and the base dielectric layer.

5. The method of claim 2 wherein forming the adjacent conductive components further comprises simultaneously forming the conductive contact and the interconnect.

6. The method of claim 1 wherein forming the adjacent conductive components further comprises:
forming a stepped contact within the via, wherein the stepped contact is within the sacrificial layer and within the base dielectric layer, wherein a stepped contact width is greater in the sacrificial layer than within the base dielectric layer, and wherein the stepped contact width changes at the interface between the sacrificial layer and the base dielectric layer; and
forming a straight contact that is within the sacrificial layer and within the base dielectric layer, wherein a straight contact width is about the same in the sacrificial layer and within the base dielectric layer.

7. The method of claim 1 wherein:
forming the via comprises forming a plurality of vias wherein the width of at least one of the vias is about constant; and
wherein forming the adjacent conductive components comprises forming a straight contact in the via, wherein the straight contact comprises a straight contact width that is about the same in the sacrificial layer and the base dielectric layer.

8. The method of claim 6 wherein forming the stepped contact further comprises forming the stepped contact such that a distance between the adjacent conductive components is a critical distance or less, wherein the air gap is formed when the distance between the adjacent conductive components is the critical distance or less.

9. The method of claim 1 wherein forming the adjacent conductive components comprises:
forming the adjacent conductive components wherein a distance between the adjacent conductive components is from about 150 nanometers to about 5 nanometers.

10. The method of claim 1 wherein forming the sacrificial layer comprises forming the sacrificial layer comprising an amorphous carbon polymer.

11. The method of claim 1 further comprising:
forming a base etch stop overlying the substrate, wherein the base dielectric layer overlies the base etch stop.

12. A method of producing an integrated circuit comprising:
forming a base dielectric layer overlying a substrate;
forming a sacrificial layer overlying the base dielectric layer;
forming a hard mask overlying the sacrificial layer, wherein the hard mask comprises a first hard mask layer, a second hard mask layer overlying the first hard mask layer, and a third hard mask layer overlying the second hard mask layer;
forming a third pattern in the third hard mask layer by removing selected portions of the third hard mask layer;
forming a second pattern in the second hard mask layer by removing selected portions of the second hard mask layer;
forming a via by removing the sacrificial layer and the base dielectric layer underlying the second pattern and removing the sacrificial layer underlying the third pattern such that a width of the via changes at an interface of the sacrificial layer and the base dielectric layer; and
forming a conductive component in the via.

13. The method of claim 12 wherein forming the conductive component comprises forming adjacent conductive components; the method further comprising:
removing the sacrificial layer from between the adjacent conductive components to define an air gap therebetween; and
forming a cap dielectric layer overlying the air gap.

14. The method of claim 12 wherein forming the conductive component comprises simultaneously forming a conductive contact and an interconnect, wherein the conductive contact extends through the sacrificial layer and the base dielectric layer, and the interconnect overlies the base dielectric layer.

15. The method of claim 14 wherein forming the conductive contact comprises forming a stepped contact, wherein the stepped contact has a stepped contact width that is greater in the sacrificial layer than within the base dielectric layer, and wherein the stepped contact width changes at the interface between the sacrificial layer and the base dielectric layer.

16. The method of claim 14 wherein forming the conductive contact comprises forming a straight contact, wherein the straight contact has a straight contact width that is about the same in the sacrificial layer and in the base dielectric layer.

17. The method of claim 12 further comprising:
removing the base dielectric layer underlying the second pattern before removing the sacrificial layer outside of the second pattern and underlying the third pattern.

18. The method of claim 17 wherein forming the via further comprises:
removing a base etch stop directly underlying the second pattern, wherein the base etch stop underlies the base dielectric layer.

19. The method of claim 12 wherein forming the conductive component comprises forming a conductive contact in electrical connection with a component contact.

20. An integrated circuit comprising:
a base dielectric layer overlying a substrate;
a sacrificial layer overlying the base dielectric layer;
adjacent conductive components disposed within the base dielectric layer and within the sacrificial layer, wherein the adjacent conductive components comprise a stepped contact and a straight contact, wherein the stepped contact comprises a stepped contact width that changes at an interface between the base dielectric layer and the sacrificial layer;
an air gap defined between the adjacent conductive components, wherein the air gap is further defined overlying the base dielectric layer;
a seal layer overlying the adjacent conductive components and the base dielectric layer; and
a cap dielectric layer overlying the air gap, wherein the cap dielectric layer underlies the seal layer.
